(19) United States
(12) Patent Application Publication
(10) Pub. No.: US 2020/0019063 A1
(43) Pub. Date: Jan. 16, 2020

(54) METHOD FOR NICKEL ETCHING

(71) Applicants: ZHENG ZUO, LOS ANGELES, CA (US); NA REN, LOS ANGELES, CA (US); RUIGANG LI, LOS ANGELES, CA (US)

(72) Inventors: ZHENG ZUO, LOS ANGELES, CA (US); NA REN, LOS ANGELES, CA (US); RUIGANG LI, LOS ANGELES, CA (US)

(73) Assignee: AZ Power, Inc, CULVER CITY, CA (US)

(21) Appl. No.: 16/386,785

(22) Filed: Apr. 17, 2019

Related U.S. Application Data
(60) Provisional application No. 62/697,244, filed on Jul. 12, 2018.

(51) Int. Cl. G03F 7/40; G03F 7/32; G03F 7/38

(52) U.S. Cl. CPC G03F 7/40; G03F 7/38; G03F 7/32

(57) ABSTRACT

In one aspect, a method for nickel etching may include steps of depositing a nickel metal layer on a substrate; pattering a photoresist layer on the nickel metal layer; oxidizing the nickel metal layer that is not covered by the photoresist layer to form an oxidized nickel metal layer; and removing the photoresist layer; and etching the nickel metal layer using the oxidized nickel metal layer as a mask. An image reverse technique is used here to form the oxidized nickel metal layer because the oxidized nickel metal layer is resistant to wet etching etchants, so the oxidized nickel metal layer can be used as a real mask for etching.

### CROSS-REFERENCE TO RELATED APPLICATIONS

This application claims priority under 35 U.S.C. § 119 (e) to U.S. Provisional Patent Application Ser. No. 62/697,244, filed on Jul. 12, 2018, the entire contents of which are hereby incorporated by reference.

### FIELD OF THE INVENTION

The present invention relates to an etching method, and more particularly to a method for nickel etching.

### BACKGROUND OF THE INVENTION

Conventionally, when etching a subject material, a resistance film may be formed on a substrate surface and used as a mask for etching. For nickel metal etching, wet etching with commercial etchants is usually adopted in the industry. However, nickel is very easy to be oxidized in the air or cold water, and the oxidized layer forming on the surface of the nickel is highly resistant to chemical reaction with the etchant. So, the result of nickel wet etching of nickel is highly unrepeatable, which may cause problems in subsequent fabrication processes. Therefore, there remains a need for a new and improved fabrication technique for nickel etching to overcome the problems presented above.

### SUMMARY OF THE INVENTION

It is an object of the present invention to provide a fabrication technique for nickel etching to achieve high selectivity and repeatability.

It is another object of the present invention to provide a nickel etching method utilizing an image reverse photolithography technique.

It is a further object of the present invention to provide a nickel etching technique utilizing the oxidized nickel metal layer that is highly resistant to chemical etchans as a “real mask” for nickel etching.

In one aspect, a method for nickel etching may include steps of depositing a nickel metal layer on a substrate; pattering a photoresist layer on the nickel metal layer; oxidizing the nickel metal layer that is not covered by the photoresist layer to form an oxidized nickel metal layer; removing the photoresist layer; and etching the nickel metal layer using the oxidized nickel metal layer as a mask.

In one embodiment, before deposition, the substrate is fully cleaned with RCA standard clean method and piranha solvent. In another embodiment, the nickel metal layer can be deposited by thermal evaporation, e-beam evaporation, sputtering, etc. In a further embodiment, oxygen plasma bombarding is used to form the oxidized nickel metal layer on the surface of nickel metal layer that is not covered by the photoresist.

In one embodiment, the photoresist layer can be removed by acetone. In another embodiment, the photoresist layer can be removed by isopropanol. In a further embodiment, the nickel etchants may include HNO₃, HF, H₃PO₄, HCl, a combination of HNO₃ and HF with a predetermined ratio, a combination of HNO₃ and HCl with a predetermined ratio.

### BRIEF DESCRIPTION OF THE DRAWINGS

FIG. 1 is a flow diagram illustrating the nickel etching method in the present invention.

FIG. 2 illustrates a substrate with a nickel metal layer formed on the substrate surface in the present invention.

FIG. 3 illustrates a photoresist layer formed on the nickel metal layer in the present invention.

FIG. 4 illustrates oxygen plasma bombarding the exposed nickel metal layer in the present invention.

FIG. 5 illustrates the formation of the oxidized nickel metal layer in the present invention.

FIG. 6 illustrates a removal of the photoresist layer in the present invention.

FIG. 7 illustrates a nickel wet etching process using the oxidized nickel metal layer as the mask in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

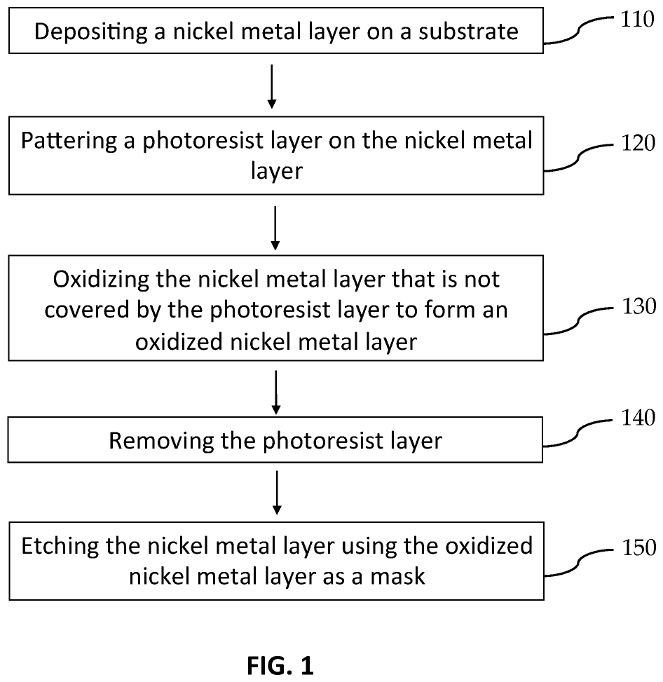

In one aspect, as shown in FIG. 1, a method for nickel etching may include steps of depositing a nickel metal layer on a substrate 110; pattering a photoresist layer on the nickel metal layer 120; oxidizing the nickel metal layer that is not covered by the photoresist layer to form an oxidized nickel metal layer 130; removing the photoresist layer 140; and etching the nickel metal layer using the oxidized nickel metal layer as a mask 150.

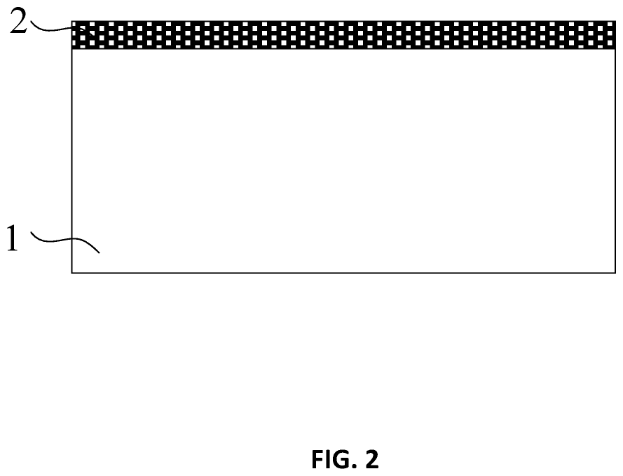

More specifically, as shown in FIG. 2, nickel metal layer 2 can be deposited on the substrate 1. Before deposition, the substrate 1 is fully cleaned with RCA standard clean method and piranha solvent. In one embodiment, the nickel metal layer 2 can be deposited by thermal evaporation, e-beam evaporation, sputtering, etc.

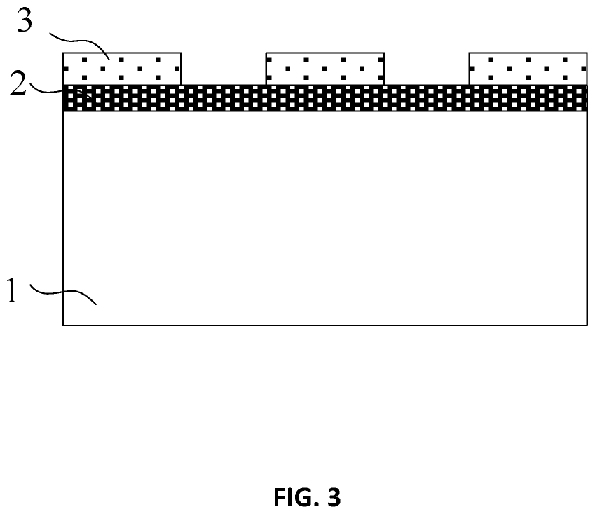

Subsequently, as illustrated in FIG. 3, a photoresist layer 3 is formed on the surface of the nickel metal layer 2 by an image reverse photolithography process, which is a process to reverse the tone of positive photoresists. Like a negative photoresist, areas that are exposed become “protected”, while the unexposed areas will be developed away.

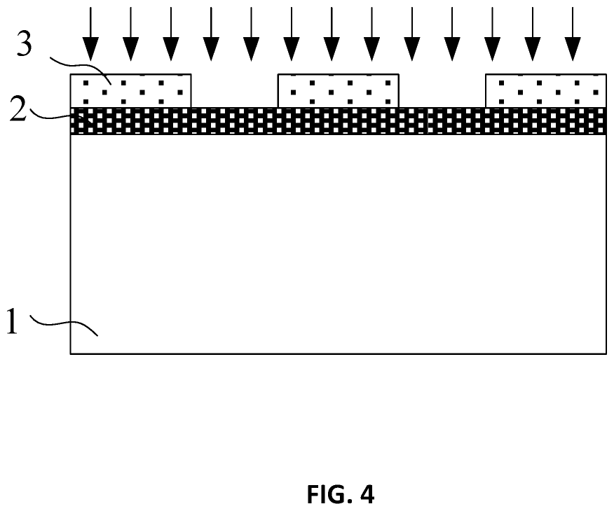

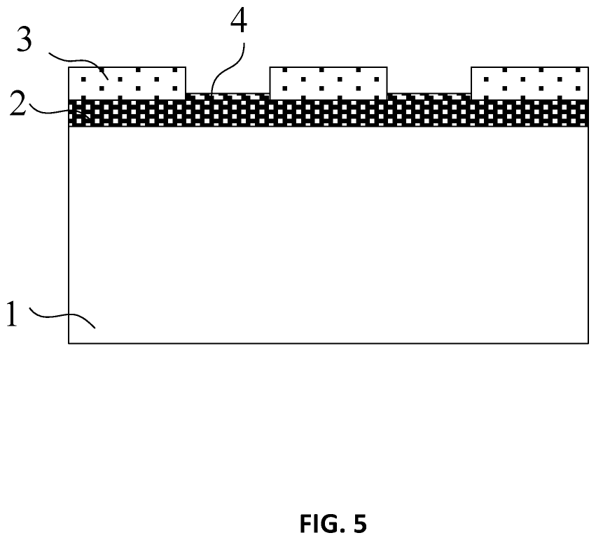

As shown in FIGS. 4 and 5, an oxidized nickel metal film 4 is formed. In one embodiment, oxygen plasma bombarding is used to form the oxidized nickel metal layer on the surface of nickel metal layer 3 that is not covered by the photoresist 3. It is noted that the power, energy and time duration for the bombardment is optimized for the best performance.

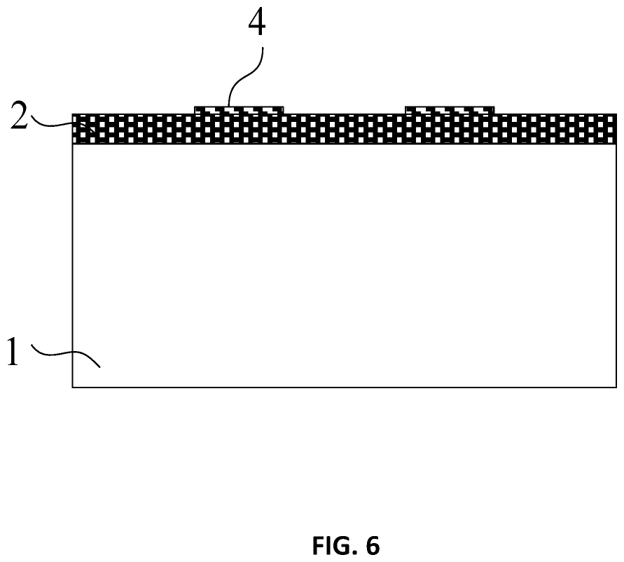

It is important to note that the image reverse technique is used here because as stated above, the oxidized nickel metal layer 4 is resistant to wet etching etchants, so the oxidized nickel metal layer 4 formed in open regions can be used as a real mask for etching. In one embodiment, after the lithography, the photoresist is baked at 110° C. for several minutes to remove the extra water and vapor and make it hard. The photoresist layer 3 is then removed as shown in FIG. 6. In one embodiment, the photoresist layer 3 can be removed by acetone. In another embodiment, the photoresist layer 3 can be removed by isopropanol.

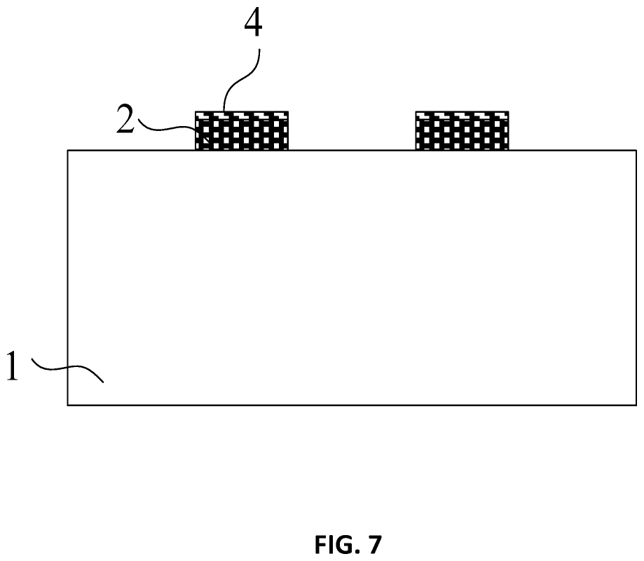

Finally, as shown in FIG. 7, the nickel metal layer 2 that is not covered by the oxidized nickel metal layer 4 is etched by the etchant using the oxidized nickel metal layer 4 as the mask layer. Because the oxidized nickel metal layer 4 is highly resistant to the etchant, the etching selectivity and repeatability can be significantly improved. The nickel etchants may include HNO₃, HF, H₃PO₄, HCl, a combination of HNO₃ and HF with a predetermined ratio, a combination of HNO₃ and HCl with a predetermined ratio, etc.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A method for nickel etching may include steps of:
depositing a nickel metal layer on a substrate;
pattering a photoresist layer on the nickel metal layer;
oxidizing the nickel metal layer that is not covered by the photoresist layer to form an oxidized nickel metal layer;
removing the photoresist layer; and
etching the nickel metal layer utilizing the oxidized nickel metal layer as a mask.

2. The method for nickel etching of claim 1, wherein the nickel metal layer is deposited by, but not limited to thermal evaporation, e-beam evaporation, sputtering.

3. The method for nickel etching of claim 1, wherein the oxidized nickel metal layer is formed by oxygen plasma bombarding.

4. The method for nickel etching of claim 1, wherein the photoresist layer is baked at 110° C. for a predetermined amount of time to remove extra water and vapor therein.

5. The method for nickel etching of claim 1, wherein the photoresist layer is removed by acetone.

6. The method for nickel etching of claim 1, wherein the photoresist layer is removed by isopropanol.

7. The method for nickel etching of claim 1, wherein the substrate is fully cleaned with RCA standard clean method and piranha solvent before the nickel metal layer is deposited thereon.
